(19) United States
(12) Patent Application Publication
(10) Pub. No.: US 2005/0186513 A1
(43) Pub. Date: Aug. 25, 2005

(54) Liquid and method for liquid immersion lithography

(76) Inventors: Martin Letz, Klein-Wintemheim (DE); Konrad Knapp, Jena (DE); Hauke Esemann, Woerrstadt (DE); Andreas Voitsch, Jena (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 10/784,922

(22) Filed: Feb. 24, 2004

(51) Int. Cl. G03F 7/00

(52) U.S. Cl. 430/320; 430/322; 430/449

(57) ABSTRACT

The present invention relates to a new class of compound useful as liquid for immersion lithography, said liquid comprising molecules so that said liquid is substantially transparent at a wavelength used for said liquid immersion lithography, wherein a degree of polarization of light, which is incident on a sample of said liquid in a forward direction and which is scattered in a direction perpendicular to said forward direction within a plane of scattering defined by said forward direction and said direction perpendicular to said forward direction, is larger than 0.9. Suited liquids are, for example, such comprising molecules transparent to UV radiation, wherein said molecules are high-symmetric molecules. Suited compounds are defined by
A(R)₄
wherein A is defined to be a 4-valent element and R is selected from —(C)ₙ— and —(Si)ₙ—, with n=1 to 10, wherein the remaining valences of the carbon or silica are saturated by one (or more) selected from hydrogen and a halogen. The invention further relates to a method for exposing a photoresist layer on a semiconductor substrate for producing microelectronic circuits or micro-electromechanical systems (MEMS). The method uses a step of liquid immersion lithography using a liquid according to the invention.

### FIELD OF THE INVENTION

The invention relates to liquids used for manufacturing semiconductor devices and more particularly, to immersion liquids used by immersion type projection exposure apparatus for lithographically printing fine circuit patterns or micro-electromechanical systems (MEMs) on a substrate, such as a wafer, during semiconductor manufacturing processes. Further, the invention relates to a method for manufacturing semiconductor devices and more particularly, to a method for lithographically printing fine circuit patterns or micro-electromechanical systems (MEMs) on a substrate, such as a wafer, during semiconductor manufacturing processes using a liquid immersion technique.

### BACKGROUND OF THE INVENTION

As is well known in the art the resolution Δx that can be achieved in lithographically forming patterns in photoresist layers on semiconductor surfaces is limited by the Abbe formula Δx=0.61 λ/NA, where λ is the optical wavelength used and NA is the numerical aperture of the optical system used for exposure. Accordingly, in order to reduce the achievable resolution Δx, the wavelength should be reduced and the numerical aperture NA should be increased.

For this purpose U.S. Pat. No. 5,610,683 proposed immersing the wafer in a high index of refraction liquid, in which case the achievable resolution is given by eq. (1)

$$Δ x = \frac{0.61 {λ}_{eff}}{NA} = \frac{0.61 λ}{{NA}_{eff}} \qquad ( 1 )$$

More specifically, when applying immersion fluids in optical microlithography a liquid is placed between the last lens of the imaging optics and the wafer. This fluid has a refractive index n_{fl}, which is larger than one. It can be either understood as reducing the wavelength of the radiation λ_{eff}→λ/n_{fl} or as increasing the numerical aperture NA_{eff}→h_{fl}NA. In this way it allows to reduce the smallest resolvable structure Δx as expressed in the Abbe formula.

Accordingly, the reduction of the achievable resolution Δx is dominated by the real refractive index of the immersion fluid. However, as is well known in the art a fluid has other optical properties besides real refractive index. The fluid can absorb radiation which will mainly increase its temperature. Furthermore, the fluid can scatter light due to a variety of processes. Scattering however is very crucial, since it gives rise to light on positions on the photoresist where no light exposure is intended. In other words, scattering reduces the imaging contrast. Mechanisms for scattering that have been investigated in the prior art are for example:
scattering on molecular vibrations (Raman scattering)
scattering on bubbles (of micrometer or nanometer size) which will be described by Mie theory
scattering on density fluctuations

Liquids useful for UV immersion lithography need to fulfil various requirements. Of course they need to be stable under UV irradiation and transparent at the wavelength used for immersion lithography. According to WO 02/093261, partially fluorinated polymers are suited in applications requiring transparency in the ultraviolet and vacuum ultraviolet. WO 02/091078 discloses perfluoropolyether (PFPE) based media, useful between two optical surfaces. U.S. Pat. No. 6,221,281 refers t a liquid immersion oil which is used in optical systems, including a polyoefine or a liquid copolymer of butylenes and another olefine, blended with an aromatic compound and optionally a paraffin compound.

Experiments have, however, revealed that scattering from molecules of immersion liquids known in the prior art comprises unexpectedly large contributions.

It is therefore an object of the present invention to provide liquids for use in liquid immersion lithography, enabling higher resolutions to be achieved.

It is another object of the present invention to provide liquids for use in liquid immersion lithography, enabling a more efficient and economical exposure of photoresist layers on semiconductor substrates. It is an object of another highly interrelated aspect of the present invention to provide a novel class of immersion liquids having unprecedented features for enabling higher resolutions to be achieved.

According to another aspect of the invention a novel method for exposing a photoresist layer on a semiconductor substrate is to be provided for producing microelectronic circuits with even higher resolutions. According to a further aspect of the invention a novel method for exposing a photoresist layer on a semiconductor substrate is to be provided for producing microelectronic circuits making use of novel immersion liquids offering unprecedented advantages, in particular with regard to production yield, achievable resolution, compatibility of the immersion liquid with the optical system used for exposure and the like.

Still further, it has now surprisingly been found that high-symmetric molecules are suited to avoid UV light scattering to a high extend. Due to this advantageous property, such compounds are superior as compared to compounds known from the art with respect to their suitability to be used in liquid immersion lithography. It is assumed that the symmetric nature of the compounds and their related small anisotropic properties avoid scattering effects occurring due to orientation fluctuation. Such an effect has not yet been reported.

### SUMMARY OF THE INVENTION

The present invention refers to a new class of compounds useful as liquid for immersion lithography, said liquid comprising molecules so that said liquid is substantially transparent at a wavelength used for said liquid immersion lithography, wherein a degree of polarization of light, which is incident on a sample of said liquid in a forward direction and which is scattered in a direction perpendicular to said forward direction within a plane of scattering defined by said forward direction and said direction perpendicular to said forward direction, is larger than 0.9.

For example, the liquid for UV immersion lithography suited in accordance with the present invention comprises molecules transparent to UV radiation, wherein said molecules are high-symmetric molecules. In accordance with a preferred embodiment, said liquid is a mixture comprising at least two different types of high-symmetric molecules. According to the present invention, high-symmetric molecules are defined to have an n-fold rotational axis, wherein n is larger than 2, and at least one of a mirror plane and a centre of inversion. Preferred symmetries of said molecules are a tetrahedral, octahedral or icosahedral symmetry. According to preferred embodiments, the tetrahedral symmetry is a symmetry in accordance with point group T_{d}, the octahedral symmetry is a symmetry in accordance with point group Oₕ and the icosahedral symmetry is a symmetry in accordance with a point group selected from Iₕ and I. Suited compounds are such defined by
A(R)₄,
wherein A is defined to be a 4-valent element and R is selected from —(C)ₙ— and —(Siₙ—, with n=1 to 10, more preferably 1 to 5, wherein the remaining valences of the carbon or silica are saturated by one (or more) selected from hydrogen and a halogen. The 4-valent element is selected from C, Si, Ge, Sn, Pb, Zr, Ti, Te, Se, Hf, Mn, Fe, Co, Ni, Pd, Pt, preferably from C and Si. The halogen is one selected from F, Cl and Br, with F being preferred. For the residue R saturated alky residues, branched or unbranched, optionally substituted by halogen, preferably fluoro, are suited. Examples for R are CF₃ or SiF₃. One suited compound is C(CF₃)₄.

Impurities, which are defined to be molecules which do not show the required high symmetry, are below 10 ppm.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 shows a method for measuring an anisotropic part of the polarizability of the molecules used for liquid immersion lithography for characterizing molecules according to the present invention.

FIG. 2 shows a schematic sectional view of an optical system used for liquid immersion lithography according to the present invention.

### DESCRIPTION OF THE PREFERRED EMBODIMENTS

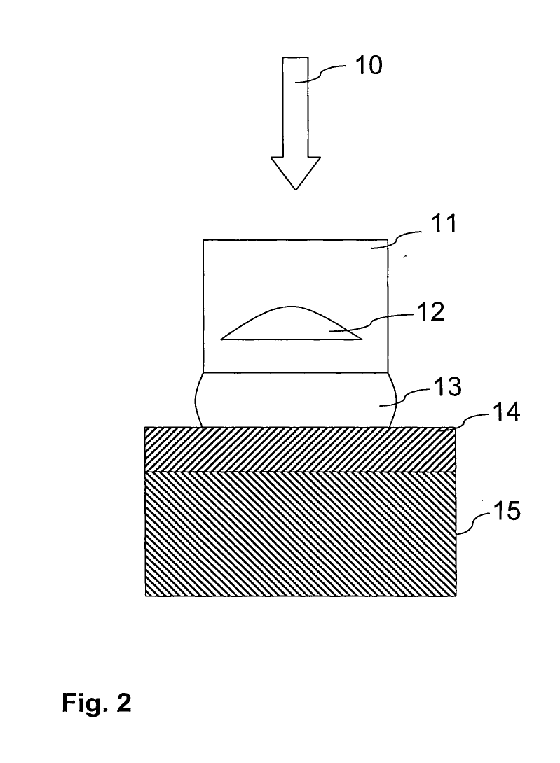

Referring to FIG. 2, a method for exposing a photoresist layer on a semiconductor substrate using a liquid immersion technique according to the present invention will be described. As shown in FIG. 2, a semiconductor substrate 15 is held in place with high precision. For this purpose, the semiconductor substrate 15 can be held by a chuck, e.g. a vacuum chuck (not shown). A mechanism for moving the exposing light beam 10 and the semiconductor substrate 15 relative to each other is provided in the conventional manner. Preferably, relative motion is indexed so that the semiconductor substrate 15 rests while being exposed by the exposing light beam 10 and is moved by a predetermined distance between individual exposing light shots so that the entire relevant surface of the photoresist layer 14 is finally patterned. The optical system shown in FIG. 2 can be part of a conventional wafer stepper as is apparent to the person skilled in the art.

Referring to FIG. 2, a photoresist layer 14 is provided on the surface of the semiconductor substrate 15 of a predetermined thickness and material. The exposing light beam 10 is imaged via the optical system 11 onto the photoresist layer 14. For enabling high resolutions, the exposing light beam 10 preferably has a small wavelength, preferably in the ultraviolet spectral range. As will become apparent to the person skilled in the art, according to the present invention arbitrary light sources may be used for generating the exposing light beam 10. Preferably the exposing light beam 10 is generated by a laser light source emitting coherent laser light.

As is known in the prior art, KrF excimer lasers with a wavelength of λ=248 nm, ArF excimer lasers having a wavelength of λ=193 nm or fluorine excimer lasers (F₂) having a wavelength of λ=157 nm are preferably used for exposing the photoresist layer 14 on the semiconductor substrate 15.

As shown in FIG. 2, the optical system 11 comprises a last optical element 12 disposed in close vicinity to the surface of the photoresist layer 14. With other words, the last optical element 12 is the most downstream optical element of the optical system 11. As is apparent to the person skilled in the art, the optical elements of the optical system 11 must be transparent to the optical wavelength used for liquid immersion lithography. As according to preferred embodiments of the present invention, liquid immersion lithography is performed in the ultraviolet spectral range, more specifically at 193 nm or 157 nm, the optical elements of the optical system 11, including the last optical element 12, may be manufacture from calcium-fluoride crystals which are available from Schott Lithotec, Jena (Germany).

As shown in FIG. 2, an interspace is provided between the last optical element 12 and the surface of the photoresist layer 14. As is known in the prior art, if air would be provided in the above interspace alone, numerical apertures Na larger than 1 are hardly achievable. Thus, the resolution of the optical system 11 is limited to a value given by the well-known Abbe formula and is dependent on the refractive index of the above interspace.

As shown in FIG. 2, for increasing the numerical aperture Na of the last optical element 12, an immersion liquid 13 is provided in the form of a thin liquid layer or bubble in the above interspace. More particularly, the immersion liquid 13 is in contact both with the last optical element 12 and the surface of the photoresist layer 14. As is known from immersion lithography according to the prior art, the achievable numerical aperture of the last optical element 12 can be increased by the ratio of the refractive index of the immersion liquid 13 to the refractive index of air.

The immersion liquid 13 between the last optical element 12 and the photoresist layer 14 to be exposed must have an index of refraction >1, have a low optical absorption at the wavelength of the exposing light beam 10, must be compatible with the material of the photoresist layer 14 and with the material of the last optical lens 12, must be uniform and non-contaminating. Candidate immersion liquids for use according to the present invention are defined in the claims.

As will be derived in sections 1. to 6. below, the immersion liquid according to the present invention effectively reduces scattering contributions due to orientation motions of the molecules of the immersion liquid to unprecedented low levels. Thus, according to the present invention the resolution that can be achieved with the optical system shown in FIG. 2, can be substantially lowered, thus enabling manufacturing of even smaller structures on semiconductor substrates, e.g. for integrated circuits (ICs) or micro-electromechanical systems (MEMs).

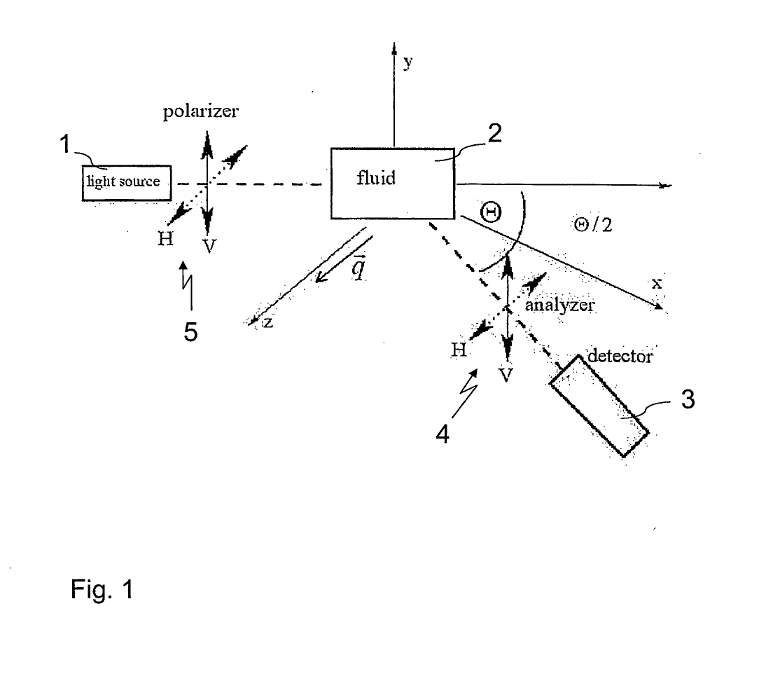

As is known in the prior art, scattering from liquid molecules causes a certain depolarization of light scattered by a fluid. Referring to FIG. 1, a method in accordance with the present invention for measuring scattering contributions due to an unisotropic part of the polarizability of molecules of the immersion liquid will be explained in detail. According to the present invention, the measuring method illustrated in FIG. 1 is a preferred manner of characterizing optical and scattering properties of molecules of the immersion liquid. It is to be noted that the below method for characterizing the optical and scattering properties of the immersion liquid represents only one preferred approach for characterizing relevant properties of the immersion liquid, several other approaches of equal significance being necessary as well for fully describing the gist of the present invention. While experimental results to be obtained with the below measuring method, might be closely related to other properties of the molecules of the immersion liquid, like symmetry, point symmetry group of the molecules and/or chemical structure, characterization of the molecules by symmetry, point symmetry groups and chemical structure might also be deemed as a completely independent manner for characterizing the relevant properties of the molecules of the immersion liquid. In particular, it is noted that the above approaches for characterizing the molecules, namely the experimental approach explained with reference to FIG. 1 below, and the approach of characterizing the molecules by symmetry operations, point symmetry groups and/or chemical structure, might, from case to case, cause deviating results, which is believed to justify characterization of the molecules by various different approaches as set forth below in the dependent claims.

As shown in FIG. 1, a light beam emitted from the light source 1 into a so-called forward direction is incident onto a sample of the immersion fluid or liquid 2. Optical characterization of the immersion fluid or liquid 2 may be performed at a wavelength identical to that used for liquid immersion lithography, in particular at a wavelength in the ultraviolet wavelength range as specified above, or may be characterized by using a light beam of a wavelength different to that used during liquid immersion lithography. In the following it is assumed that the light beam emitted by the light source 1 is not polarized.

As shown in FIG. 1, a light detector 3 is provided at a scattering angle θ, which according to the present invention is preferably set to θ=π/2. Thus, the forward direction and the direction perpendicular to the forward direction for illuminating light scattered by the immersion fluid or liquid 2 into the light detector 3, span a plane of scattering, which lies, in the case of FIG. 1, in the drawing plane of FIG. 1. In the following, it is assumed that unpolarized light emitted by the light source 1 is scattered by the immersion fluid or liquid 2 under a scattering angle θ=π/2, while an analyzing polarisator 4, which is disposed upstream of the light detector 3, is rotated.

According to the measuring method according to the invention the degree of polarization of light scattered by the immersion fluid or liquid into the light detector 3 can be expressed in various different manners. For example, the above degree of polarization can be expressed by a ratio of a maximum intensity detected by the light detector 3 at a first rotatory position of the analyzing polarizer 4 and the minimum light intensity detected by the light detector 3 at a second rotatory position of the analyzing polarizer 4 different from the above first rotatory position.

Preferably, according to the invention, the degree of polarization is defined by P=Iₚₑᵣₚ/Iₚₐᵣ, wherein Iₚₑᵣₚ is an intensity of light measured downstream of the analyzing polarizer 4 by the light detector 3 when a transmission axis of this polarizer 4 is perpendicular to the above plane of scattering, and wherein Iₚₐᵣ is an intensity of light measured downstream of the analyzing polarizer 4 by the light detector 3, when a transmission axis for the polarizer 4 is parallel to the plane of scattering.

According to a first preferred embodiment of the present invention, the degree of polarization measured in the above manner is larger than 0.9. According to a second preferred embodiment of the present invention the above degree of polarization is larger than 0.95, due to an even higher degree of symmetry of molecules of the immersion fluid or liquid.

As is apparent to the person skilled in the art, a degree of polarization of the scattered light can also be measured in a similar manner when the light beam emitted by the light source is polarized perpendicular to the above plane of scattering (reference numeral V, shown in FIG. 1) or when the light incident on a sample of the immersion fluid or liquid 2 is polarized parallel, i.e. lies within the above plane of scattering (reference numeral H, shown in FIG. 1).

In the following, namely in sections 1. to 5. including the Appendix A., a theoretical model of the inventors for identifying the sources of the unexpected contributions in light scattering in immersion liquids will be discussed for enabling a better understanding of the novel and unprecedented features and advantages of the present invention. In the following, reference will be made to immersion liquids like highly-purified water known from the prior art.

1. Introduction

Besides the real refractive index a fluid has other optical properties. The fluid can absorb radiation which will mainly increase its temperature. The fluid can further also scatter light due to a number of processes. Scattering however is very crucial, since it results in light occuring on positions on the photoresist where no light exposure is intended. With other word scattering reduces the imaging contrast. Mechanisms for scattering are for example
scattering on molecular vibrations (Raman scattering)
scattering on bubbles (of micrometer or nanometer size) which will be described by Mie theory
scattering on density fluctuations

The density is a function of the thermodynamic variables pressure and temperature. Therefore the scattering due to density fluctuations has two parts. One is scattering due to pressure fluctuations or longitudinal sound waves. This is the Brillouin scattering. The scattering due to temperature fluctuations causes a central line with a width given by the thermal diffusivity.

As the inventors have found out, in a molecular fluid there is a further scattering mechanism. It is caused by the fact that the molecular polarizability is anisotropic. In this case a rotation (or libration) motion of the molecules will lead to a fluctuation of the polarizability. In a gas the individual molecule can freely rotate which leads to the (quantized) “butterfly wings” in the spectrum of a molecular gas. In a fluid the rotation motion is strongly overdamped but contains also collective contributions which lead to a damped broad orientation mode. This vibration mode has the ability to scatter light. In the present work we calculate the contribution of scattering due to orientation motion. This is done for water where the molecular polarizability is known. For three further molecules, which are close in composition to the fluorinated polymers discussed as immersion liquids for both 193 nm and 157 nm radiation, we calculate the molecular polarizability using an abinitio method.

The theory of light scattering is outlined in many textbooks. The details of scattering on molecular orientations among with the coupling to hydrodynamic modes is also well known in the art. For water the application of light scattering as an immersion fluid is known in the art.

The following is organized as follows: In section 2 we show on the example of the water molecule how the tensor of the molecular polarizability is related to its isotropic and anisotropic parts. In sec. 3 we explain how the tensor of the molecular polarizability can be calculated using density functional theory. To benchmark the calculation the molecular polarizability for the water molecule is calculated in sec. 3.1. In the following sec. 3.2 we have chosen three molecules which come close to molecular fluids under discussion for liquid immersion fluids. The theory of light scattering in a molecular fluid 4 and its application are shortly reviewed in sec. 4.1. The resulting scattering contributions for the molecular fluids are summarized in sec. 5 and are given in the table 1.

2. The Local Polarizability of Water

We start with the static anisotropic polarizability of water which is well known in the literature. In general this molecular polarizability is also dependent on the thermodynamic parameters (e.g. temperature and pressure) and on the wavelength of the radiation. We assume throughout this work that its anisotropy remains constant. Since we calculate relative intensities between scattering on the isotropic part and the anisotropy, we can start our calculation with the static anisotropic polarizability. In molecular units α₀³ (α₀ is the Bohr radius with 0.528 Å) and in the coordinate system with axes along the main polarizability directions of the water molecule it reads:

$$α = ( \begin{matrix}10.311 \pm 0.088 & 0 & 0 \\ 0 & 9.549 \pm 0.088 & 0 \\ 0 & 0 & 9.907 \pm 0.02\end{matrix} ) \qquad ( 2 )$$

In general the polarizability is as well a function of the thermodynamic parameters (p,T) as well of the wavelength, λ. In the following we assume that the relation between the isotropic part and the anisotropic part of the polarizability is a constant even up to the vicinity of the absorption edge. The polarizability, Eq. (2), can be expanded with respect to its irreducible spherical components. As a result we obtain three components of the water polarizability:

$$\begin{matrix}α = {\sum }_{l , m} {α}_{l , m} \\ with & ( 3 ) \\ {α}_{0 , 0} = - \sqrt{3} a = - \sqrt{3} 9.92 \\ {α}_{2 , 0} = \sqrt{\frac{2}{3}} g = \sqrt{\frac{2}{3}} ( - 0.56 ) \\ {α}_{2 , 2} = {α}_{2 , - 2} = - 0.2 & ( 4 )\end{matrix}$$

The first contribution with α=9.92 is the isotropic polarizability, the second with g=−0.56 the deviations from isotrop symmetry which still fulfill cylinder symmetry (cigar- of pancake-shape deviations) and the third contribution are deviations from the cylinder symmetry. In the following we neglect the last term. A numerical study of water shows that even the dynamics of water can be reasonably well reproduced when neglecting the last term in Eq. (4).

3. Abinitio Calculation of the Molecular Polarizability

A molecule can have permanent dipole \vec{p} and molecular polarizability α. An external electrical field \vec{E} induces a dipole moment α \vec{E}. The total Energy of such a molecule in an electrical field is:

$$U = {U}_{0} - \vec{p} \vec{E} - {\int }_{0}^{\vec{E}} \underline{\underline{α}} {\vec{E}}^{′} ⅆ {E}^{′} = {U}_{0} - \vec{p} \vec{E} - \frac{1}{2} {E}^{T} \underline{\underline{α}} \vec{E} \qquad ( 5 )$$

where U₀ is the energy of the molecule in the absence of the electrical field. We calculated the energy and polarization for zero electrical field and at least three absolute values of the electrical field between 0 and 0.02 (au) using an abinitio method with an atomic basis set. To obtain the starting configuration and the values of U₀ and \vec{p} a geometry optimization was performed first. The electric field in atomic units (au) is measured in units of Eₕ/(ea₀)≈5.1410¹¹ V/m where Eₕ is the energy in units Hartree, e the electron charge and α₀ the Bohr radius. This was done for the electric field pointing in the directions: (100), (010), (001), (110), (101), (011). Eq. (5) allows to calculate the matrix elements of the polarizability tensor α. Therefore the energy resulting from a density functional calculation is expressed as a second order polynomial of the electric field \vec{E}. The expansion coefficients from all six directions under consideration allow to determine the matrix elements of α. Finally α was diagonalized to obtain it in the coordinate system of its principal axes.
3.1. Comparing Calculation and Experiment for Water

The first system where we apply our calculation is the water molecule. Here we have accurate molecular polarizabilities from the literature (see sec. 2) and it allows us to estimate the accuracy of our calculation. For water we obtain:

$$α = ( \begin{matrix}9.47 & 0 & 0 \\ 0 & 8.96 & 0 \\ 0 & 0 & 7.81\end{matrix} ) \qquad ( 6 )$$

Comparing to eq. (2) we see that we obtain the molecular polarizability of the water molecule with an accuracy of 15%. This 15% accuracy is the accuracy with which we can determine the isotropic part of the polarizability. For the anisotropic part however, the accuracy is much smaller, since it is obtained by differences of the matrix elements of the polarizability.

3.2. Results for Other Molecules

We now apply the procedure mentioned above to several other molecules. The molecules are chosen in a way that they resemble further fluids which are under discussion for liquid immersion lithography. In the following three systems for the molecular structure of the molecules we considered are discussed. The first system, CF₃—CHF—O—(CF₂)₂—CF₃, comes close to freon (with the restriction, that we used a very small chain length compared to real freon). For the molecular polarizability we obtain:

$$α = ( \begin{matrix}96.49 & 0 & 0 \\ 0 & 74.66 & 0 \\ 0 & 0 & 72.92\end{matrix} ) \qquad ( 7 )$$

An expansion with respect to spherical invariants like in Eq. (3) leads for the isotropic part to
α_{fr}=81.36 (8)
and for the anisotropic part to
g_{fr}=−12.66 (9)

The second system, CF₃—CF₂—O—(CF₂)₂—CF₃, comes close to Krytox. It is very similar to the molecule calculated above and therefore also the polarizability should be similar. As a result we obtain for the polarizability:

$$α = ( \begin{matrix}97.06 & 0 & 0 \\ 0 & 75.02 & 0 \\ 0 & 0 & 74.77\end{matrix} ) \qquad ( 10 )$$

An expansion with respect to spherical invariants as in Eq. (3) leads for the isotropic part to
α_{fr}=82.28 (11)
and for the anisotropic part to
g_{fr}=−11.26 (12)

As a next system we investigated perfluoro-N-methylnorpholine, CF₃—NOC₄F₈. The resulting polarizability is:

$$α = ( \begin{matrix}90.20 & 0 & 0 \\ 0 & 87.88 & 0 \\ 0 & 0 & 73.58\end{matrix} ) \qquad ( 13 )$$

An expansion with respect to spherical invariants like in Eq. (3) leads for the isotropic part to
α_{fr}=83.88 (14)
and for the anisotropic part to
g_{fr}=−15.46 (15)

All three molecules have much larger polarizabilities than water in well agreement with their high refractive indices which makes them interesting candidates for immersion fluids.

4. Theory of Light Scattering and its Application

Using standard theories to describe the scattering of light in a molecular liquid by taking into account the direct scattering contributions only (no dipole induced dipole contributions) one gets the expressions for the different polarization dependent scattering contributions which are shown in appendix A. This treatment does include the scattering due to density fluctuations (dn/dp) and orientational fluctuations. The scattering due to vibrational modes (Raman scattering) is not included. The scattering due to thermal fluctuations (dn/dT) can be incorporated in an established way. Note that the contributions due to the Lorenz-Lorentz equation are automatically obtained in the equations (18). The full two particle correlations which are probed by a light scattering experiment are further included. The full quasi elastic equations are given in appendix A. If we are (i) not interested in a detailed dynamic scattering information but rather in the overall scattering we can sum over all dynamic scattering contributions by performing a frequency integration. In FIG. 1 we define the convention used to define directions with respect to the scattering plane. The scattering vector q lies in the scattering plane and its absolute value is bounded between forward scattering with q=0 and backward scattering with q=4π/λ, by 0<q<4π/λ. The polarization directions for the different symmetry components of the scattering contribution e.g. VV are defined by the polarization direction of the incident radiation and the direction of observation relative to the scattering plane.

4.1 Scattering of Light in a Molecular Liquid

If we account for the wave vectors probed by light scattering—even in the DUV wavelength range —Eqs. (24) can be evaluated in the limit of small wavevectors q→0. Here we further assume that the main axes of the polarizability tensor point along the same axes as the one for the tensor of the moments of inertia. Taking into account the isotropic and the anisotropic scattering contribution one obtains for the scattering of water in the limit of small wavevectors:

$$\begin{matrix}{I}^{VV} ( λ ) = f ( λ ) ( {a}^{2} S ( q -> 0 ) + {g}^{2} \frac{4 π}{15} \frac{4}{3} {S}_{22}^{0} ( q -> 0 ) ) & ( 16 ) \\ {I}^{VH} ( λ ) = f ( λ ) ( {g}^{2} \frac{4 π}{15} \frac{4}{3} ( q -> 0 ) ) & ( 17 ) \\ {I}^{HH} ( λ ) = f ( λ ) ( {a}^{2} {cos}^{2} ⊖ S ( q \to 0 ) + {g}^{2} \frac{π}{15} ( ( 4 + \frac{4}{3} {cos}^{2} ⊖ ) {S}_{22}^{0} ( q -> 0 ) ) ) & ( 18 )\end{matrix}$$

where α and g are the center of mass component and orientational component of the polarizability from Eq. (4), respectively. From Eqs. (16)-(18) it follows that even under 90° scattering angle (⊖=π/2) there is still radiation within both polarization directions. A value of S₂₂⁰(q→0)˜1.05 follows from molecular dynamic calculations for water. For the three other molecular fluids besides water we used for the estimation of the scattering in tab. 1 the values of S₂₂⁰(q→0) and S₂₂⁰(q→0) from water. That means that we assumed that these fluids have the same compressibility as water and also the same tendency as water to form an orientational order. This is however a very rough estimate and will have to be replaced by more accurate values when available. Note that the value of S₂₂⁰(q→0) becomes in a nematic fluid, where it has much larger values than in water, identical to the order parameter of the nematic phase.
   5. Results for Molecular Fluids

In order to characterize the scattering of a molecular fluid due to orientation motion, we define two numbers. The first one is the relation between light scattered by orientation motion and the center-of-mass scattering contribution averaged over the scattering angular ⊕.

$$\begin{matrix}{R}_{av} = \frac{1}{2} {\int }_{0}^{π} sin ⊖ ⅆ ⊖ R ( ⊖ ) \\ with & ( 19 ) \\ R ( ⊖ ) == \frac{{I}_{orientation}}{{I}_{center off mass}} = \frac{{g}^{2} \frac{4 π}{15} ( \frac{4}{3} + 2 + ( 1 + \frac{1}{3} {cos}^{2} ⊖ ) ) {S}_{22}^{0} ( q -> 0 )}{{a}^{2} ( 1 + {cos}^{2} ⊖ ) S ( q \to 0 )} & ( 20 )\end{matrix}$$

Rₐᵥ gives the amount of scattering due to orientation contributions in relation to the amount of scattering due to the center of mass contributions. It means that Rₐᵥ/(1+Rₐᵥ)=R_{eff} is the part of scattering due to orientation motion of the molecules.

The second quantity which can be easily verified in an experiment by analyzing the polarization of the scattered radiation, is the depolarization ratio.

$$\begin{matrix}P ( ⊖ ) = \frac{{I}^{VH} + {I}^{HH}}{{I}^{VV} + {I}^{HV}} \\ = \frac{{a}^{2} {cos}^{2} ⊖ {S}_{00}^{0} ( q -> 0 ) + {g}^{2} \frac{4 π}{15} ( 2 + \frac{1}{3} {cos}^{2} ⊖ ) {S}_{22}^{0} ( q -> 0 )}{{a}^{2} {S}_{00}^{0} ( q -> 0 ) + {g}^{2} \frac{4 π}{15} \frac{7}{3} {S}_{22}^{0} ( q -> 0 )}\end{matrix} \qquad ( 21 )$$

Its value can be easily evaluated under 90° scattering angular and its measurement is straight forward. In a simple liquid, where all molecules would have spherical symmetry (g=0), the depolarization ratio under 90° scattering angular is zero which means the scattered radiation under 90° scattering angular is completely polarized. The more the molecules deviate from spherical symmetry, the larger gets the depolarization ratio. In table 1 we have summarized our results for the four molecules under consideration. According to our results the fluorinated polymers have a much larger potential to scatter radiation due to orientational motion. However this result is based on our abinitio calculation which shows a reasonable accuracy only for the isotropic part of the polarizability while the anisotropic part is highly inaccurate and on the assumption that as well the compressibility (S₀₀⁰(q→0)) as well als the tendency of the molecules to form orientational order (S₂₂⁰(q→0)) where assumed to be identical to water.
6. Symmetry of Molecules

The symmetry properties of molecules are useful in a consideration of their properties. Typical symmetry operations are rotations, reflections and inversions.

Every symmetry operation has an associated symmetry element, which is the point, line or plane with respect to which the symmetry operation is carried out. Thus the symmetry operation of inversion is carried out with respect to a symmetry element which is a point (called the centre of inversion). Rotations have symmetry elements which are lines—the axes of rotation. Reflections have symmetry elements which are planes—the mirror planes.

Molecules may be classified by identifying all their symmetry elements and then grouping together all the ones which have the same number of each type of symmetry element.

These groups are known as point groups if, as is common, the classification is carried out using only those symmetry elements corresponding to operations that leave at least one point completely unchanged. As to the definition “high-symmetric” molecules which show tetrahedral, octahedral or icosahedral symmetry are high-symmetric. Due to their isotropic behaviour, such compounds are suited to effectively reduce scattering occurring in immersion liquids due to orientation motions to unexpected low levels.

7. Conclusion

In summary we found that scattering of light due to orientational contributions has to be carefully considered when applying water as an immersion liquid. Roughly 13% of overall scattering on temperature, density and orientational fluctuations in water result from orientational components. Further the orientational components lead to a polarization ratio which differs from zero. Under 90° scattering angular it is for water approximately 0.1. Even if for water the scattering on molecular orientations is not so important it seems to become a dominant scattering mechanism for further molecules under consideration. The three molecules investigated show a much larger anisotropy of their molecular polarizabilities calculated with an abinitio method. This result is however very preliminary, since the anisotropic part of the molecular polarizability lacks the desired accuracy. More accurate calculations with larger basis sets will have to be done. Furtheron we assumed for the calculation of the overall scattering of the three molecular fluids as well the compressibilities as well as the tendency to form orientation order to be identical to water. The results of the present work can be easily checked by measuring the depolarization ratio under 90° scattering angular. A series of accurate measurements (e.g. in depolarized scattering geometry) should allow to determine the parameters relevant for scattering in a molecular fluid.

Appendix A. Full Scattering Terms for a Molecular Liquid

Calculating the direct orientational and center of mass component for a molecular fluid one arrives at:

$$\begin{matrix}{I}^{VV} ( q , ω , λ ) = f ( λ ) ( {a}^{2} {S}_{00}^{′′0} ( q , ω ) + {g}^{2} \frac{4 π}{15} ( {S}_{22}^{′′2} ( q , ω ) + \frac{1}{3} {S}_{22}^{′′0} ( q , ω ) ) - ag \frac{4}{3} \sqrt{\frac{π}{5}} {S}_{20}^{′′0} ( q , ω ) ) & ( 22 ) \\ {I}^{VH} ( q , ω , λ ) = f ( λ ) ( {g}^{2} \frac{4 π}{15} ( {sin}^{2} ( ⊖ / 2 ) {S}_{22}^{′′2} ( q , ω ) + {cos}^{2} ( ⊖ / 2 ) ) {S}_{22}^{′′1} ( q , ω ) ) & ( 23 ) \\ {I}^{HH} ( q , ω ) = f ( λ ) ( {a}^{2} {cos}^{2} ⊖ {S}_{00}^{′′0} ( q , ω ) + ga \frac{2}{3} \sqrt{\frac{π}{5}} ( 3 + cos Θ ) cos ⊖ {S}_{20}^{′′0} ( q , ω , λ ) + {g}^{2} \frac{π}{15} ( \frac{1}{3} {( 3 + cos ⊖ )}^{2} {S}_{22}^{′′} ( q , ω ) ) - {( 1 + cos ⊖ )}^{2} {S}_{22}^{′′2} ( q , ω ) ) ) & ( 24 )\end{matrix}$$

Here the superscripts V and H stand for vertical and horizontal polarization of the incident (first index) and scattered (second index) light. These polarization directions are measured relative to the scattering plane. The double prime denotes the imaginary part of the density-density correlation functions. In the limit of small scattering vectors q→0 the upper index of the correlation functions which refers to the m in the spherical harmonics becomes meaning-less since S₂₂⁰(q→0)=S₂₂¹(q→0)=S₂₂²(q→0) is valid due to symmetry considerations. Further the off-diagonal components S″⁰₂₀(q,ω,λ) vanish in the limit of small wavevectors and when being reasonably far from supercooling the liquid.

Without further elaboration, it is believed that one skilled in the art can, using the preceding description, utilize the present invention to its fullest extent. The preceding preferred specific embodiments are, therefore, to be construed as merely illustrative, and not limitative of the remainder of the disclosure in any way whatsoever.

In the foregoing and in the examples, all temperatures are set forth uncorrected in degrees Celsius and, all parts and percentages are by weight, unless otherwise indicated.

The entire disclosure of all applications, patents and publications, cited herein are incorporated by reference herein.

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

1. A liquid for use in liquid immersion lithography, said liquid comprising molecules so that said liquid is substantially transparent at a wavelength used for said liquid immersion lithography, wherein a degree of polarization of light, which is incident on a sample of said liquid in a forward direction and which is scattered in a direction perpendicular to said forward direction within a plane of scattering defined by said forward direction and said direction perpendicular to said forward direction, is larger than 0.9.

2. The liquid according to claim 1, wherein said degree of polarization is larger than 0.95.

3. The liquid according to claim 1, wherein said light incident on said sample in said forward direction is not polarized and wherein said degree of polarization of said light scattered in said direction perpendicular to said forward direction is measured by rotating a polarizer within said plane of scattering defined by said forward direction and said direction perpendicular to said forward direction.

4. The liquid according to claim 3, wherein said degree of polarisation P is defined by P=Iₚₑᵣₚ/Iₚₐᵣ, wherein Iₚₑᵣₚ is an intensity of light measured downstream of said polarizer when a transmission axis of said polarizer is perpendicular to said plane of scattering and wherein Iₚₐᵣ is an intensity of light measured downstream of said polarizer when a transmission axis of said polarizer is parallel to said plane of scattering.

5. The liquid according to claim 4, wherein said degree of polarisation is measured at a wavelength used for said liquid immersion lithography, said wavelength being in an ultraviolet wavelength range.

6. The liquid according to claim 4, wherein said degree of polarisation is measured at a wavelength within a visible range of optical wavelengths.

7. The liquid according to claim 4, wherein a light source used for producing said light incident on said sample is a laser.

8. The liquid according to claim 1, wherein said liquid is a liquid of high-purity, wherein a concentration of impurities that are not high-symmetric and are present in said liquid is below 10 ppm.

9. A liquid for use in liquid immersion lithography, said liquid comprising molecules transparent to UV radiation, wherein said molecules are high-symmetric molecules.

10. The liquid according to claim 9, wherein the high-symmetric molecules have an n-fold rotational axis, wherein n is larger than 2, and at least one of a mirror plane and a centre of inversion.

11. The liquid according to claim 10, wherein a symmetry of said molecules is selected from a group consisting of tetrahedral symmetry, octahedral or icosahedral.

12. The liquid according to claim 11, wherein the tetrahedral symmetry is a symmetry in accordance with point group T_{d}.

13. The liquid according to claim 1, wherein the octahedral symmetry is a symmetry in accordance with point group Oₕ.

14. The liquid according to claim 1, wherein the icosahedral symmetry is a symmetry in accordance with a point group selected from Iₕ and I.

15. The liquid according to claim 10, wherein the concentration of impurities that are not high-symmetric is below 10 ppm.

16. The liquid according to claim 9, said liquid being a mixture comprising at least two different types of high-symmetric molecules.

17. The liquid according to claim 9, wherein an anisotropic part of a polarizability of said molecules is smaller than 15% of an isotropic part of said polarizability.

18. The liquid according to claim 17, wherein said anisotropic part of said polarizability is smaller than 10% of said isotropic part of said polarizability.

19. The liquid according to claim 17, wherein said anisotropic part of said polarizability is smaller than 5% of said isotropic part of said polarizability.

20. The liquid according to claim 17, wherein said isotropic part of said polarizablity is given by an average value of diagonal elements of a tensor of said polarizability in a coordinate system spanned by the main axes of said molecule.

21. The liquid according to claim 17, wherein said anisotropic part of said polarizability is given by difference values of diagonal elements of said tensor of said polarizability in the principle axis system.

22. A liquid for UV immersion lithography, said liquid comprising a compound defined by
A(R)₄
wherein A is defined to be a 4-valent element and R is selected from —(C)ₙ— and —(Si)ₙ—, with n=1 to 10, wherein the remaining valences of the carbon or silica are saturated by one (or more) selected from hydrogen and a halogen.

23. The liquid for UV immersion lithography according to claim 22, wherein the 4-valent element is selected from C, Si, Ge, Sn, Pb, Zr, Ti, Te, Se, Hf, Mn, Fe, Co, Ni, Pd, Pt.

24. The liquid for UV immersion lithography according to claim 22, wherein the 4-valent element is selected from C and Si.

25. The liquid for UV immersion lithography according to claim 22, wherein the halogen is one selected from F, Cl and Br.

26. The liquid for UV immersion lithography according to claim 22, wherein R is CF₃.

27. The liquid for UV immersion lithography according to claim 22, wherein R is SiF₃.

28. A method for exposing a photoresist layer on a semiconductor substrate for producing microelectronic circuits or micro-electromechanical systems (MEMS), comprising the steps:
providing a liquid comprising molecules so that said liquid is substantially transparent at a wavelength used for exposing said photoresist layer, so that a degree of polarization of light, which is incident on a sample of said liquid in a forward direction and which is scattered in a direction perpendicular to said forward direction within a plane of scattering defined by said forward direction and said direction perpendicular to said forward direction, is larger than 0.9;
providing said liquid in an interspace formed between an optical element, which is used for exposing said photoresist layer and which is arranged close to a surface of said semiconductor substrate, and said surface of said semiconductor substrate such that said interspace is substantially filled by said liquid; and
exposing said photoresist layer via said optical element for forming patterns in said photoresist layer for procucing said microelectronic circuits or micro-electromechanical systems (MEMS).

29. A method for exposing a photoresist layer on a semiconductor substrate for producing microelectronic circuits or micro-electromechanical systems (MEMS), comprising the steps:
providing a liquid comprising molecules so that said liquid is substantially transparent at a wavelength used for exposing said photoresist layer, which molecules are high-symmetric molecules;
providing said liquid in an interspace formed between an optical element, which is used for exposing said photoresist layer and which is arranged nearest to a surface of said semiconductor substrate, and said surface of said semiconductor substrate such that said interspace is substantially filled by said liquid; and
exposing said photoresist layer via said optical element for forming patterns in said photoresist layer for producing said microelectronic circuits or micro-electromechanical systems (MEMS).

30. A method for exposing a photoresist layer on a semiconductor substrate for producing microelectronic circuits or micro-electromechanical systems (MEMS), comprising the steps:
providing a liquid comprising molecules so that said liquid is substantially transparent at a wavelength used for exposing said photoresist layer, which molecules comprise a compound defined by
A(R)₄
wherein A is defined to be a 4-valent element and R is selected from —(C)ₙ— and —(Si)ₙ—, with n=1 to 10, wherein the remaining valences of the carbon or silica are saturated by one (or more) selected from hydrogen and a halogen;
providing said liquid in an interspace formed between an optical element, which is used for exposing said photoresist layer and which is arranged close to a surface of said semi-conductor substrate, and said surface of said semiconductor substrate such that said interspace is substantially filled by said liquid; and
exposing said photoresist layer via said optical element for forming patterns in said photoresist layer for producing said microelectronic circuits or micro-electromechanical systems (MEMS).
